(19) United States
(12) Patent Application Publication
(10) Pub. No.: US 2025/0379142 A1
(43) Pub. Date: Dec. 11, 2025

(54) INTERCONNECT VIA STRUCTURE PASSING THROUGH METAL LEVELS

(71) Applicant: COMMISSARIAT A L'ENERGIE ATOMIQUE ET AUX ENERGIES ALTERNATIVES, Paris (FR)

(72) Inventor: Heimanu NIEBOJEWSKI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/227,648

(22) Filed: Jun. 4, 2025

(30) Foreign Application Priority Data
Jun. 5, 2024 (FR) FR2405920

(51) Int. Cl. H01L 23/522; H01L 21/768; H01L 23/528

(52) U.S. Cl. CPC H01L 23/5226; H01L 21/76802; H01L 21/76831; H01L 21/76877; H01L 23/528

(57) ABSTRACT

A production of a microelectronic device including a substrate coated with a stack including one or more conductive tracks of a lower level coated with an “intermediate” insulating layer coated with one or more conductive tracks of an “upper” level, a conductive element passing through the intermediate insulating layer and in contact with a first conductive track of a given level from among the upper level and the lower level while being insulated, with a spacer insulating a second conductive track from another level from among the lower level and the upper level, the insulating spacer being disposed between the second conductive track and the conductive element, the conductive element having a “lower” end making contact with a first conductor or semiconductor region of the substrate or stack, the conductive element passing through the first conductive track and the second conductive track and being surrounded by the insulating spacer.

### TECHNICAL FIELD AND PRIOR ART

The present application relates to the field of microelectronics and integrated circuits and relates more particularly to the implementation of an interconnect structure, with vertical connection elements commonly called “vias”, the arrangement of which is improved.

Vias play a crucial role in the performance of electronic circuits, particularly with regard to interconnection density and electrical performance.

A via denotes an electrical connection element disposed in an opening and which passes through one or more layers or regions of a stack. This connection element is typically “vertical”, i.e. it extends orthogonally or substantially orthogonally to a main plane of a substrate on which the layers or the stack are formed. A via thus makes it possible to electrically connect regions belonging to different levels of a microelectronic device.

In some cases, regions belonging to non-adjacent levels disposed on a substrate, i.e. levels separated by one or more intermediate levels of conductive elements or of intermediate devices, must be electrically connected. For example, a track of a third metal interconnect level, commonly referred to as “metal 3” must be connected with a metal track of a first metal interconnect level, commonly referred to as “metal 1”, while avoiding making contact with a track of the intermediate metal level, in this case a second metal interconnect level, referred to as “metal 2”.

To avoid unwanted connections or to not disturb the operation of devices of intermediate levels passed through, the vertical connection elements can be formed at a certain distance from the access areas to these intermediate level devices, in other words by bypassing them.

Nevertheless, this results in a reduction in the integration density.

Document FR3030881 by the applicant presents a method for insulating certain lateral portions of a via in order to avoid unwanted electrical contact with one or more intermediate levels.

There is therefore a problem of making contacts that allow elements of non-adjacent levels to be electrically connected without this taking place at the expense of the integration density.

### DESCRIPTION OF THE INVENTION

The present invention therefore aims to provide a microelectronic device comprising:
a substrate coated with a stack comprising one or more conductive tracks of a so-called “lower” level, this lower level being coated with a so-called “intermediate” insulating layer, the intermediate insulating layer being coated with one or more conductive tracks of a so-called “upper” level,
a conductive element passing through the intermediate insulating layer and being in contact with a first conductive track of a given level between the upper level and the lower level while being insulated, by means of an insulating spacer, from a second conductive track of another level among the lower level and the upper level, the insulating spacer being disposed between the second conductive track and the conductive element, the conductive element having a so-called “lower” end making contact with a first conductor or semiconductor region of the substrate or of the stack,
the conductive element passing through the first conductive track and the second conductive track and being surrounded by the insulating spacer.

With such a device, and such an interconnect structure arrangement, connections can be made between different and non-adjacent levels while limiting overall dimensions, which helps to achieve a better integration density.

The device further comprises a second conductive element having a lower end making contact with a second conductor or semiconductor region of the substrate or of the stack, the second conductive element passing through a conductive track of the given level as well as the intermediate insulating layer and a conductive track of said other level, the second conductive element being insulated, by means of a second insulating spacer, from the conductive track of the given level through which the second conductive element passes, the second conductive element being in contact with the conductive track of the other level through which it passes.

Thanks to such an interconnect structure arrangement, independent connections can be made on two separate, stacked levels while improving the integration density.

According to one possible embodiment of the device, the conductive element and the second conductive element each pass through the first conductive track of the given level and respectively pass through the second conductive track of the other level and a third conductive track of the other level that is separate from the second conductive track, the second conductive track and the third conductive track extending parallel or substantially parallel to a first direction parallel to a main plane of the substrate, the first conductive track extending in a second direction orthogonal to the first direction, or
wherein the conductive element and the second conductive element each pass through the first conductive track of the given level and each pass through the second conductive track of the other level.

Such a structure is thus adapted in particular to creating contacts on conductive tracks of separate levels and having a crossed arrangement or of the type commonly referred to as the “crossbar” arrangement, or to creating contacts on separate levels that are parallel and stacked.

According to a possible embodiment of the device, the stack comprises a so-called “lower” insulating layer on which the one or more conductive tracks of the given level are disposed, the first region being disposed between an area of the substrate and the lower level, the conductive element further passing through the lower insulating layer.

Advantageously, the first region is a region of a semiconductor layer of the substrate or resting on the substrate.

Such a structure allows a selective contact to be made between a semiconductor layer and one or more metal interconnect levels, while limiting overall dimensions.

According to one possible particular embodiment, the first region can form a quantum island. Such a structure thus advantageously adapts to the addressing and/or biasing of a matrix quantum circuit.

According to one possible particular embodiment, the first region can be a source or drain region of a transistor. Such a structure is thus advantageously adapted to addressing and/or biasing transistors.

According to a particular embodiment, the insulating spacer can be made from a material capable of reversibly changing resistance and/or state between an amorphous phase and a crystalline phase, in particular under the effect of an electrical current.

Such a structure is thus advantageously adapted to the production of ReRAM or PCMRAM memory circuits.

Advantageously, the first region can be a region of a semiconductor layer, whereas the second region is another region of this semiconductor layer.

The present application further relates to a method for producing a microelectronic device as defined above.

According to another aspect, the present application further relates to a method for producing a microelectronic device comprising the following steps:
a) providing a substrate coated with a stack comprising one or more conductive tracks of a so-called “lower” level, the lower level being coated with a so-called “intermediate” insulating layer, the intermediate insulating layer being coated with one or more conductive tracks of a so-called “upper” level,
b) forming a first opening and a second opening in the stack and each passing through a conductive track of the upper level, the intermediate insulating layer, and a conductive track of the lower level, the first opening exposing at least a first portion and the second opening exposing at least a second portion of one or more conductive tracks of the upper level, the first opening further exposing at least a third portion and the second opening further exposing at least a fourth portion, respectively of one or more conductive tracks of the lower level,
c) forming, in the first opening, a first insulating spacer against the first portion while leaving the third portion exposed, and forming, in the second opening, a second insulating spacer against the fourth portion while leaving the second portion exposed,
d) filling the first opening and the second opening with at least one conductive material, so as to form a first conductive element and a second conductive element, the first conductive element being in contact with the third portion and being insulated from the first portion by means of the first spacer, the second conductive element being in contact with the second portion while being insulated from the fourth portion by means of the second spacer.

Advantageously, step c) can comprise at least the following steps:
c1) depositing a first thin insulating layer lining the walls of the first opening and of the second opening,
c2) partially etching the first thin insulating layer at the upper part of the first opening, so as to expose the first portion, while preserving the first thin insulating layer at the lower part of the first opening as well as in the second opening,
c3) partially etching the first portion, so as to form a cavity,
c4) depositing a second thin insulating layer lining the walls of the second opening and of the first opening, and filling the cavity at least partially,
c5) etching, one or more times, the second thin insulating layer, so as to preserve a region of the second thin insulating layer in the cavity.

According to one possible implementation, after step c1) and before step c2), the method can comprise the following steps:
depositing at least one sealing material for sealing off the first opening and the second opening,
forming a masking opposite the second opening and comprising a window opposite the first opening,
etching, through said window, the at least one sealing material in an upper part of the first opening while preserving the sealing material in a lower part of the first opening, the method further comprising, after step c2) and before step c3):
removing the sealing material from the first opening and second opening.

According to one possible implementation of the method, the first thin insulating layer and the second thin insulating layer can be respectively made from at least one first material and at least one second material that is different from the first material, the step c5) of etching, one or more times, the second thin insulating layer being carried out by selectively etching the second material with respect to the first material, followed by anisotropically etching the first thin insulating layer.

According to one possible implementation of the method, the substrate or the stack can comprise a semiconductor layer coated with at least one so-called “lower” insulating layer, the lower insulating layer being coated by the one or more conductive tracks of the lower level and in which method, in step b) of forming a first opening and a second opening, the first opening and the second opening are formed so as to pass through the lower insulator layer until reaching the semiconductor layer.

According to one possible implementation of the method, the first opening and the second opening can be formed simultaneously in step b) and the filling of the first opening and of the second opening in step d) is advantageously carried out simultaneously in the first opening and in the second opening.

### BRIEF DESCRIPTION OF THE DRAWINGS

The present invention will be better understood after reading the following description of example embodiments, which is intended for purposes of illustration only and is not intended to limit the scope of the invention, and with reference to the accompanying drawings, wherein:

FIG. 1, FIG. 2, FIG. 3, FIG. 4A, FIG. 4B and FIG. 5 illustrate the production of different levels of conductive tracks on a substrate.

FIG. 6 illustrates the production of via openings through different levels of conductive tracks.

FIG. 7, FIG. 8A, FIG. 8B, FIG. 9, FIG. 10, FIG. 11, FIG. 12, FIG. 13, FIG. 14A and FIG. 14B illustrate one embodiment of insulating spacers in the openings passing through the tracks, at least one spacer being formed against a track of an upper level, and at least one other spacer being formed against a track of a lower level.

FIG. 15A, FIG. 15B and FIG. 15C illustrate the filling of the via openings and an interconnect structure thus obtained.

FIG. 16 illustrates an example of an interconnect structure according to the invention formed on a substrate of the semiconductor on insulator type.

FIG. 17 illustrates a contacting of an interconnect structure on conductor or semiconductor regions which may be different.

FIG. 18 illustrates an interconnect structure provided with vias passing through a kth and a (k+1)^{th} metal interconnect level.

FIG. 19 illustrates a particular example of an interconnect structure formed of conductive vias each passing through the same conductive track of an upper level and the same conductive track of a lower level.

FIG. 20A and FIG. 20B illustrate a particular example of an interconnect structure for controlling a quantum island or qubit matrix.

FIG. 21 illustrates an alternative embodiment of an interconnect structure contacting regions of a component on either side.

FIG. 22A and FIG. 22B illustrate an interconnect structure provided with a via forming a memory element and associated with a transistor.

FIG. 23 illustrates an interconnect structure provided with a conductive via and capable of forming, with a conductive track through which it passes and an insulating spacer arranged between the track and the via, a ReRAM or PCRAM memory element.

Identical, similar or equivalent parts of the different figures bear the same reference numerals so as to facilitate the transition from one figure to another.

The individual parts shown in the figures are not necessarily displayed according to a uniform scale in order to make the figures easier to read.

Furthermore, in the description below, the terms that depend on the orientation of the structure, such as “above”, “below”, “lower”, “upper”, “juxtaposed”, “stacked”, “vertical” or “horizontal” apply on the assumption that the structure is oriented as illustrated in the figures.

### DETAILED DISCLOSURE OF PARTICULAR EMBODIMENTS

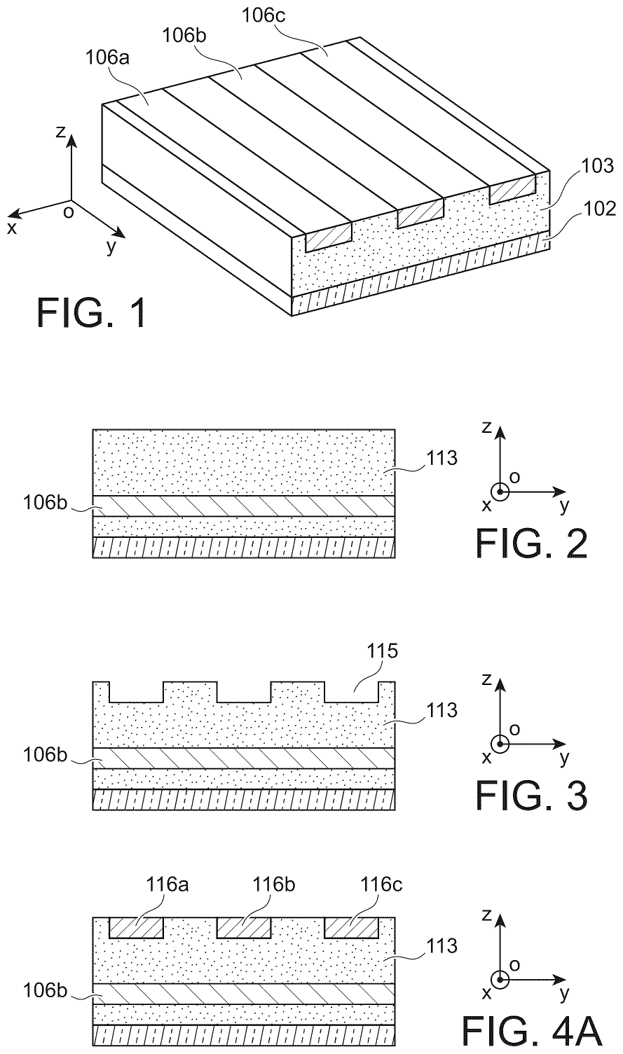

Reference is firstly made to FIG. 1 (which in this case gives a perspective view), which illustrates a step of an example method for manufacturing an interconnect structure.

The starting material of the method in this case comprises a layer 102 which can be conductive and in particular metallic, or semi-conductive, and on which contact is to be made, this layer 102 belonging to a substrate or resting on a substrate (the substrate not being shown in this figure).

The layer 102 is first coated with a so-called “lower” insulating layer 103, for example made of SiO₂ or formed of a stack, for example of the PMD (“Pre-Metal Dielectric”) type comprising a layer of SiO₂ deposited on an etch stop layer made, for example, of SiN.

One or more conductive tracks are formed on the insulating layer 103 and belong in this case to a so-called “lower” metal interconnect level, for example corresponding to the lower metal interconnect level M1 commonly referred to as “metal 1”. In the particular example shown, tracks 106a, 106b, 106c are in particular produced, in this case taking the form of metal lines, for example made of copper.

In this case, these tracks 106a, 106b, 106c extend mainly in a direction parallel to a direction y and a main plane of the substrate. Here and throughout the description, the “main plane” of the substrate is understood to refer to a plane passing through the substrate and parallel to the plane [O;x;y] of an orthogonal coordinate system [O;x;y;z] given in FIG. 2 (this plane also being parallel to the layer 102).

An example method for producing the tracks 106a, 106b, 106c uses a Damascene-type technique where trenches, in this case oblong trenches, are made in the insulating layer 103, after which the trenches are filled with a metal material. This filling can be followed by a polishing step CMP (“Chemical Mechanical Planarization”) in order to remove metallic material overflowing from the trenches onto the insulating layer 103.

A similar succession of steps to those described above can then be repeated, this time in order to form one or more conductive tracks 116a, 116b, 116c of an upper metal interconnect level, corresponding, for example in this case, to a second metal interconnect level M2 commonly referred to as “metal 2”.

The tracks 106a, 106b, 106c of the lower level M1 are thus coated (FIG. 2 giving a cross-sectional view this time) with at least one other so-called “intermediate” insulating layer 113, which can have a composition similar to that of the lower insulating layer 103, for example containing SiO₂, and/or which can be formed of a stack of a plurality of insulating materials such as a stack of SiN and SiO₂.

Trenches 115, in this case oblong trenches, are then made in the intermediate insulating layer 113 (FIG. 3).

The trenches 115 are then filled with a metal material. This filling can be followed by a polishing step CMP (“Chemical Mechanical Planarization”) in order to remove metallic material overflowing from the trenches onto the insulating layer 113.

The trenches 115, and the tracks 116a, 116b, 116c produced by filling these trenches 115 are provided such that they extend parallel to a main plane of the substrate.

In this particular example illustrated in FIG. 4A-4B (giving a cross-sectional view and a top view respectively), the tracks 116a, 116b, 116c in the form of metallic lines, for example copper lines, belong to an upper metal interconnect level, in particular to the second metal interconnect level M2 commonly referred to as “metal 2”. The tracks 116a, 116b extend mainly in a direction parallel to a second direction x, which is therefore orthogonal to that in which the tracks 106a, 106b, 106c of the lower level extend.

A so-called “upper” insulating layer 123 can then be deposited (FIG. 5) on the level M2 of conductive tracks 116a, 116b, 116c. Again, the “upper” insulating layer 123 can be, for example, a silicon oxide layer or a stack of dielectric materials with an etch stop layer for example made of SiN overlaid with a layer of SiO₂.

Openings 125a, 125b, 125c are then formed in the stack formed previously. These openings 125a, 125b, 125c, which in this case preferably extend in a vertical direction, in other words orthogonally to the main plane of the substrate, respectively expose, and advantageously pass through, the conductive tracks 116a, 116b, 116c, of the upper level M2. Each of these openings 125a, 125b, 125c also passes through the intermediate insulating layer 113 between the levels M1 and M2, and also exposes, and advantageously passes through, a conductive track 106a of the lower level M1. The etching of the openings 125a, 125b, 125c can be stopped on a layer located below the lower level M1.

In particular, an opening 125b exposes a portion 1161 of the conductive track 116b of the upper level M₂ through which it passes and a portion 1061 of the track 106a of the lower level M1 through which it passes. An opening 125a exposes a portion 1162 of the conductive track 116a of the upper level M2 through which it passes and a portion 1062 of the track 106a of the lower level M1 through which it passes.

In the particular example of the method described here, these openings 125a, 125b, 125c also pass through the lower insulating layer 103 located between the level M1 and the semiconductor or conductor layer 102, and expose the semiconductor or conductor layer 102. In particular, it is provided that the bottom 127f of the openings 125a, 125b, 125c reveals the semiconductor or conductor layer 102.

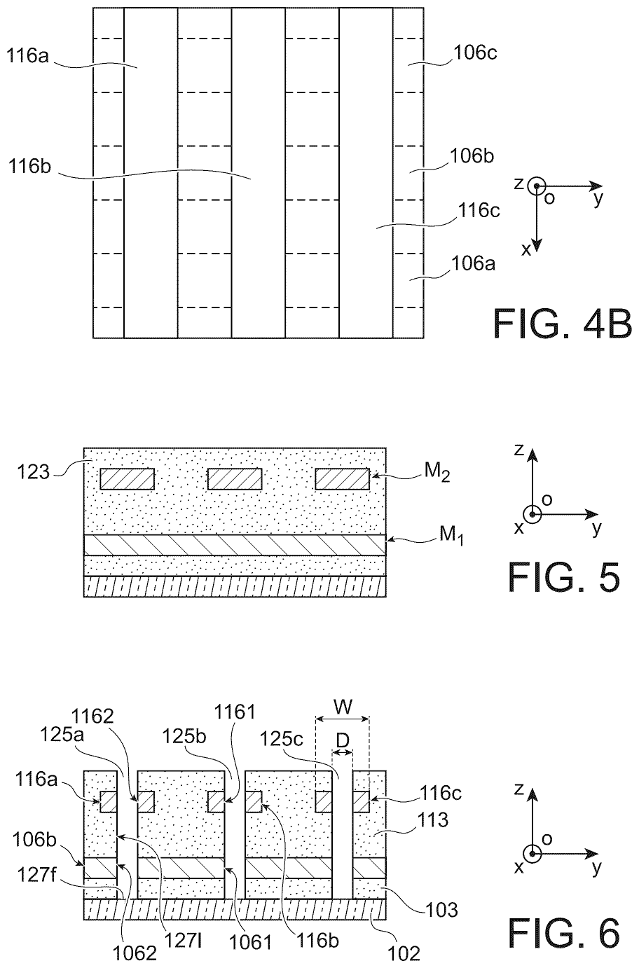

The production of the openings 125a, 125b, 125c typically comprises a lithography step. The openings 125a, 125b, 125c here have a diameter or a width D (dimension measured parallel to the y-axis in FIG. 6), which is intended to be smaller than the width W of the conductive tracks 116a, 116b, 116c, 106a, 106b, 106c, where D is, for example, in the region of 40 nm, and the width W of the tracks being, for example, between 100 nm and 200 nm. W-D is typically at least equal to 60 nm.

Anisotropic dry etching can be carried out to etch the stack and advantageously in this case pass through two metal levels M1, M2. For example, plasma etching using at least one of the following compounds: CCl₄, SiCl₄, Cl₂, HBr, CH₃ and COOH, can be carried out to pass through two levels of copper tracks.

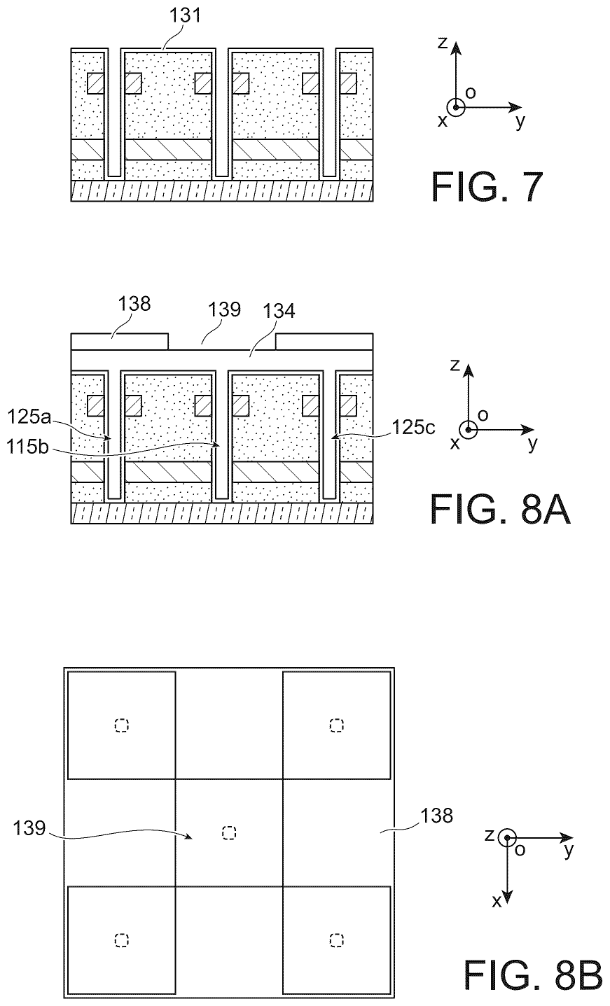

Then, a first thin insulating layer 131, with a thickness comprised, for example, between 5 nm and 10 nm, is deposited, lining the side walls 127l and bottom walls 127f of the openings 125a, 125b, 125c. This thin insulating layer 131 also referred to as a “liner” can be produced by conformally depositing a dielectric material, for example chosen from among the following materials: SiN, SiBCN, SiOCN, SiCO, HfO₂, TiO₂, Al₂O₃ (FIG. 7).

A targeted protection of the upper part of one or more given openings from the set of openings 125a, 125b, 125c made is then carried out.

For this purpose, a method comprises a step of sealing all of the openings 125a, 125b, 125c, by depositing at least one material 134 for filling the openings 125a, 125b, 125c. In the example embodiment illustrated in FIG. 8A, the filling material 134 is deposited so as to fill the openings 125a, 125b, 125c. The filling material 134 can, for example, be a layer of the SOC (“spin-on-carbon”) type, typically having a polymer material base, for example PGMEA (propylene glycol methyl ether acetate) with a carbon proportion typically greater than 80%, and can fill the openings 125a, 125b, 125c preferably over the entire depth thereof.

A masking 138 is then formed, in this example on a layer of the filling material 134 that extends beyond the mouth of the openings 125a, 125b, 125c. This masking 138 is distributed in a targeted manner facing one or more given openings 125a, 125c from among the apertures 125a, 125b, 125c, filled with the filling material 134 while retaining one or more windows 139, i.e. one or more holes disposed opposite one or more other openings from among the openings 125a, 125b, 125c filled with the material 134. Advantageously, the masking 138 formed, for example, of a photosensitive resin can be disposed on an intermediate anti-reflective layer (not shown), for example a silicon (SiARC) layer, which is itself disposed on the filling material 134.

A masking block opposite one or more tracks 116a, 116c can be provided, above a succession of tracks in a direction orthogonal to these tracks, while disposing a window 139 opposite one or more other tracks 116b. According to a particular possible arrangement of the masking 138, the latter is arranged opposite one in every two tracks. Thus, in the particular example embodiment illustrated in FIG. 8A and 8B (giving a cross-sectional view and a top view respectively), for example, a staggered arrangement of windows 139 is provided.

Partial removal of the filling material 134 revealed by the one or more windows 139 is then carried out. In particular, an upper portion of filling material 134 located in the upper part of the one or more openings 125b concerned and disposed opposite a window 139 is removed. Thus, the filling material 134 is etched so as to leave it only in the lower part of the one or more openings 125b not covered by the masking 138 (FIG. 9). This partial etching of the filling material 134 can be carried out using plasma, for example a fluorocarbon plasma.

This removal is followed by etching a part of the first thin insulating layer 131 revealed by the one or more windows 139 and not covered or protected by the filling material 134. Thus, the first thin insulating layer 131 is removed in the upper part of the one or more openings 125b disposed opposite a window 139 (FIG. 10). Selective isotropic wet etching can be implemented to perform this removal. In the particular case, for example, where the thin insulating layer 131 is made of SiN, this etching can be implemented using H₃PO₄. At the end of this step, one or more openings 125a, 125c are provided with a bottom wall and side walls fully covered by the thin layer 131, whereas one or more openings 125b are covered with the thin layer 131 only at their lower portion so as to cover the track 106a of the lower level M1.

A portion 1161 of conductive track 116b of the second level M2 is thus again exposed in each opening 125b where these removals are carried out, whereas in the extension at the bottom of this or these same one or more openings 125b, a track 106a of the lower level M1, through which this opening 125b passes in this case, remains protected by the filling material 134 and by the first thin insulating layer 131.

A partial etching can then be carried out on the exposed portion 1161 of the one or more tracks 116b not protected by the first thin insulating layer 131.

For this purpose, the filling material 134, as well as the masking 138, can be removed beforehand, as illustrated in FIG. 11. Such a removal, in particular when the material 134 is a polymer and the masking 138 is a photosensitive resin, can be carried out by a removal method commonly referred to as “stripping” using, for example, an organic solvent, for example an acetone solvent.

The partial etching of the exposed portion 1161 of the one or more tracks 116b in the upper part of the opening 125b is carried out so as to form a cavity 140 in the side wall 1271 of the opening 125b and exposing a remaining etched portion 1161′ of the conductive track 116b. Selective wet etching, for example by means of a solution comprising a heated mixture of hydrogen peroxide (H₂O₂) and sulfuric acid (H₂SO₄), commonly referred to as “hotSPM” or TMAH (acronym for “TetraMethylAmmonium Hydroxide”) can in particular be used when the portion 1161 of conductive track 116b to be etched is made of polysilicon or a metal such as copper. Partial etching aims to remove a thickness of conductive material in the order of that of a liner, and in particular of a second thin insulating layer intended to be deposited at a later time. This second thin insulating layer can be provided with a thickness in the order of that of the first thin insulating layer 131 and/or for example comprised between 5 and 10 nm.

Then (FIG. 12), the second thin insulating layer 141 covering the side walls and the bottom of the openings 125a, 125b, 125c is deposited. This second thin insulating layer 141, with a thickness comprised for example between 5 nm and 10 nm, can be produced by conformal deposition of a material which can be dielectric and chosen, for example, from the following materials: SiN, SiBCN, SiOCN, SiCO, HfO₂, TiO₂ and Al₂O₃.

The thin insulating layer 141 can be of the same nature as the thin layer 131 or advantageously made of a material that is different from that of the first thin insulating layer 131.

According to a particular embodiment, the thin insulating layer 141 can be a layer of variable resistivity intended to form a non-volatile memory element, in particular a layer such as that used in RRAM or ReRAM (“Resistive Random Access Memory”), whose change in resistance makes it possible to record information. In this case, the thin insulating layer 141 can in particular be an oxide layer (e.g. HfO₂, TiO₂, or Al₂O₃) commonly used in OxRAM structures.

According to another particular embodiment, the thin insulating layer 141 can be a phase-change material layer, for example to form a memory of the PCM (“Phase Change Memory”) type, capable of changing from an amorphous state to a crystalline state and vice versa. For example, a chalcogenic material such as GST (for GeSbTe or chalcogenide glass) can be used.

The second thin insulating layer 141 is deposited so as to line the side and bottom walls of the openings 125a, 125b, 125c and fill at least partially the cavity 140 previously made by etching the conductive track 125b in the opening 116b.

The second thin insulating layer 141 is then partially etched. Such an etching is carried out so as to remove this second thin insulating layer 141 everywhere in the openings 116a, 116c and in the opening 116b, preferably while retaining it at least partially in the cavity 140 formed previously by etching the track 116b. Selective etching with respect to the material of the first thin insulating layer 131 can be performed when the second thin insulating layer 141 is made of a different material. Such an etching step can be carried out by wet etching, for example using HF or by dry etching, for example using a CF₄/Ar type plasma, or even by a combination of these two types of etching.

Thus, a part of the second thin insulating layer 141 is retained at least against the conductive track 116b of the second level M2 exposed by the opening 125b. The retained part of the second thin insulating layer 141 thus forms an insulating seal, also referred to as a “spacer” 141e, disposed against the exposed portion of the conductive track 116b (FIG. 13).

A step of etching the first thin insulating layer 131 is then carried out so as to retain only regions of the first thin insulating layer 131 in the lower part of the openings 125a, 125c, from which the second thin layer 141 has been completely removed and which do not comprise a spacer 141e formed from such a layer 141. The retained regions of the first thin insulating layer 131 thus form an insulating seal referred to as a “spacer” 131e against portions of the conductive track 106a (FIG. 14A and 14B respectively giving a cross-sectional view and a top view).

In a case where the thin insulating layers 131, 141 are of different natures, the one or more spacers 131e are formed by performing an anisotropic etching step on the first thin insulating layer 131e. This etching is pushed to beneath the second level M2 and preferably without reaching the lower level M1.

Such an etching step can be carried out by dry etching, for example using a CF₄/O₂ type plasma.

Alternatively, in the case where the thin layers 131 and 141 are of the same nature and have identical compositions, the partial removal of the second thin layer 141 and of the first thin layer 131 to form the spacers 131e, 141e can be carried out by a single anisotropic plasma etching of these thin layers 131, 141.

A deposition of conductive material 150 is then carried out in order to fill the openings 125a, 125b, 125c and form vertical conductive elements 156a, 156b, 156c commonly referred to as “vias”. A conformal metal deposition of one or more of the following materials: Ti, TiN, W, Cu, Ta, Co or Ru, can, for example, be carried out. Such a deposition is typically followed by a CMP planarization step on the excess material likely to overflow beyond the mouth of the openings 125a, 125b, 125c.

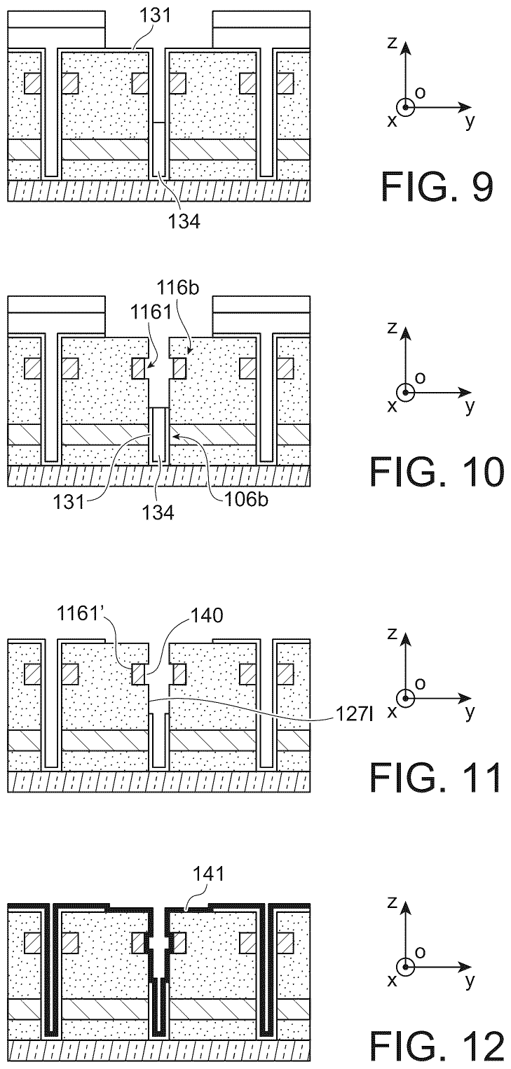

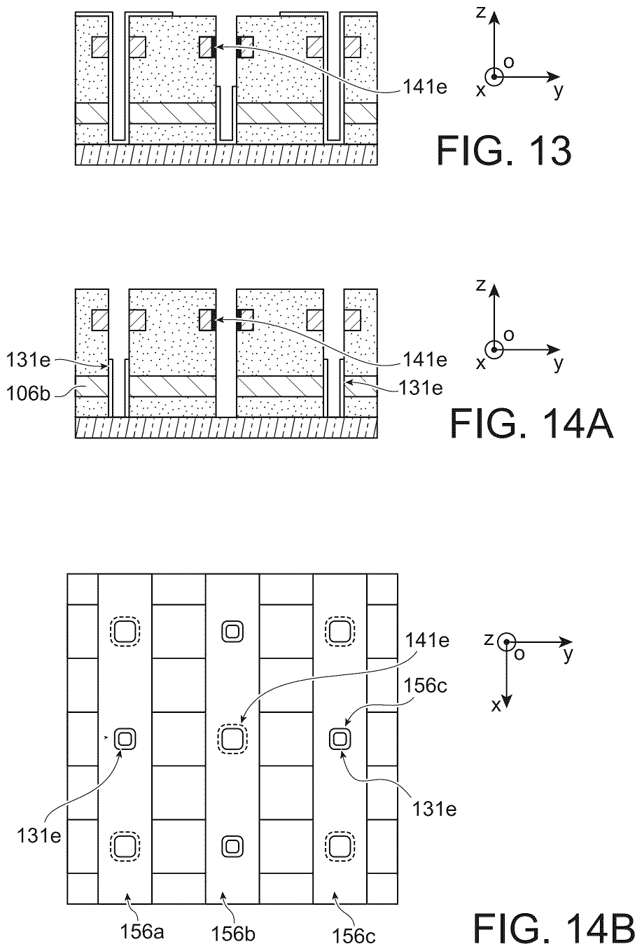

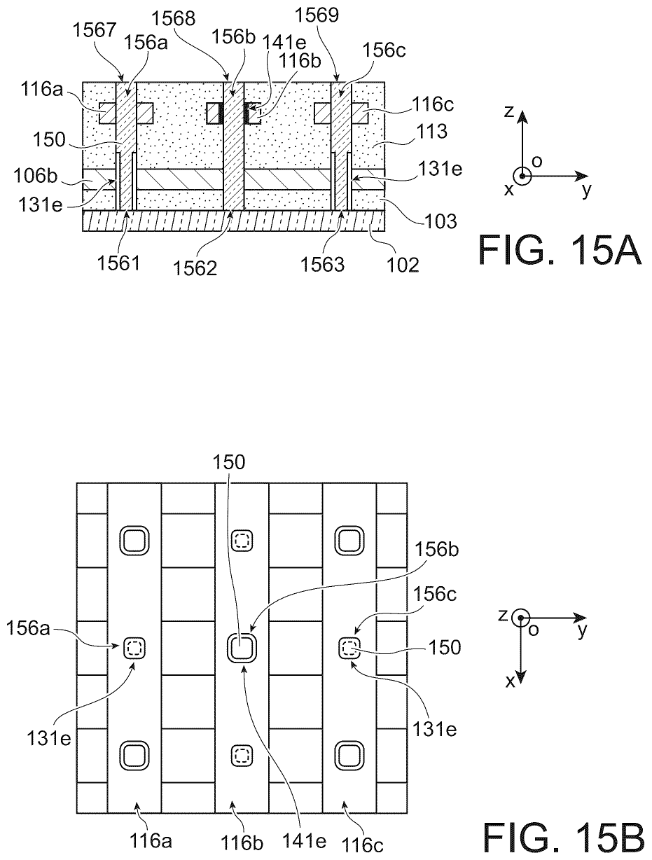

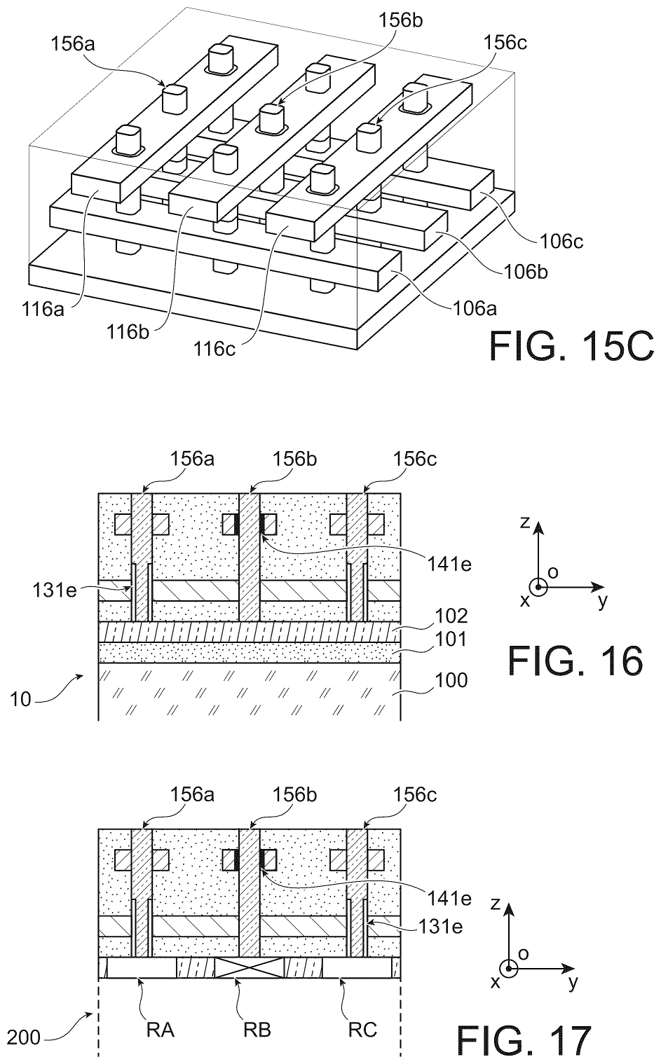

An interconnect structure is then obtained as illustrated in FIG. 15A-15C (giving a cross-sectional view, a top view and a perspective view, respectively).

The structure is provided with conductive elements 156a, 156b, 156c or “vias” each passing through the intermediate insulating layer 113 between the levels M2 and M1, and the insulating layer 103 located below the lower level M1, to make contact via their respective lower ends 1561, 1562, 1563 with the conductor or semiconductor layer 102.

Among these conductive elements 156a, 156b, 156c, the given conductive elements 156a, 156c are in contact respectively with conductive tracks 116a, 116c of the upper level M2 through which they respectively pass while being insulated, via the insulating spacer 131e, from the same conductive track 106a of the first level M1 through which they each also pass.

At least one other conductive element 156b is in contact with the conductive track 106a of the lower level M1 through which it passes while being insulated, via the insulating spacer 141e, from a conductive track of the second level M2 through which it also passes.

At each conductor track of the lower level M1 or upper level M2, the conductive elements 156a, 156b, 156c are, in this case, surrounded and typically completely surrounded by material of this conductor track.

The spacers 131e, 141e advantageously produce an insulating closed contour forming a sleeve or a ring around their respective conductive through-element or via, which is itself typically entirely surrounded by the conductive material of the track through which the conductive element or via passes.

Typically, the conductive elements 156a, 156b, 156c have respective upper ends 1567, 1568, 1569 which extend beyond the upper level M2 and each protrude from a conductive track of the upper level M2 and respective lower ends 1561, 1562, 1563, which extend beyond the lower level M1 and each protrude from a conductive track of the lower level M1 to reach an area between the substrate and the lower level M1.

An interconnect structure is produced here that makes it possible to make inter-level connections while avoiding interconnecting tracks of directly adjacent or neighboring levels M1, M2 and having a compact arrangement favorable to a high integration density.

Such an interconnect structure with through-vias results in a significant gain in integration density. Thanks to the spacers 131e, 141e, there is no need to bypass a metal level to which it is not desired to be electrically connected.

In the example embodiment just described, the conductive elements 156a, 156b, 156c have respective lower ends 1561, 1562, 1563 making contact with the same conductor or semiconductor layer 102.

This layer 102 can advantageously be a semiconductor layer commonly referred to as an “active layer” of a substrate or resting on a substrate and in which components or parts of components, for example such as transistors, are made or intended to be made.

Thus, one particular example embodiment provides, as a starting structure for carrying out a method of the type described above, a substrate 10 of the semiconductor-on-insulator type as illustrated in FIG. 16, for example of the SOI (“Silicion On Insulator”) type having a semiconductor support layer 100, for example made of silicon, coated with an insulating layer 101, for example made of SiO₂, and commonly referred to as BOX (“buried-oxide”), the insulating layer 101 being itself coated with the semiconductor layer 102 forming, in this case, the surface layer of the substrate. Such a surface semiconductor layer can, for example, be made of silicon, SiGe, or Ge.

An alternative structure is given in FIG. 17, with a block 200 in a discontinuous line diagrammatically representing a substrate coated with one or more layers or a stack with which regions RA, RB, RC, to be contacted, are flush. These regions RA, RB, RC are typically conductive or semiconductive but have different compositions between them. For example, one or more regions is or are made of a first metal or semiconductor material, whereas at least one other region is made of a second material, for example a semiconductor material that is different from the first material. The respective lower ends 1561, 1562, 1563 of the conductive elements 156a, 156b, 156c respectively make contact on these regions RA, RB, RC.

In the example described previously, the formed vias pass through conductive tracks of a lower level M1 which can be the first metal interconnect level and of an upper level M2, which can be the second metal interconnect level. However, a similar method can be implemented on other metal interconnect levels.

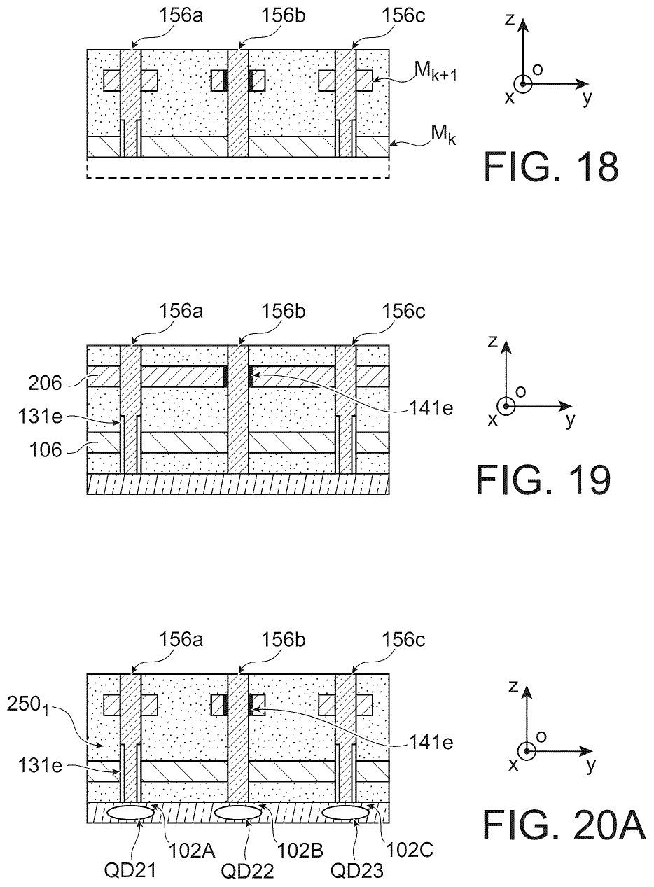

Thus, in the alternative embodiment illustrated in FIG. 18, the conductive elements 156a, 156b, 156c, each pass through a conductive track of a (k+1)^{th} level (where k is an integer greater than 1) and a track of a kth level, while being both in electrical contact with a conductive track of the kth level and insulated from a track of the (k+1)^{th} level, or while being both in electrical contact with a track of the (k+1)^{th} level and insulated from a track of the k^{th} level.

In the example method described previously in connection with FIGS. 1 to 15A-15C, the conductive elements 156a, 156b, 156c pass through conductive tracks of an upper level that are orthogonal to one or more tracks of a given lower level. An alternative embodiment illustrated in FIG. 19 provides conductive elements 156a, 156b, 156c, each passing through the same conductive track 216 of an upper level and each passing through the same conductive track 106 of a given lower level, the conductive tracks 116 and 106 extending mainly in respective directions parallel to each other and in FIG. 19 parallel to the y-axis of the orthogonal coordinate system [O;x;y;z].

An interconnect structure as described above is particularly suitable for addressing qubits, in particular spin qubits provided in semiconductor regions forming quantum dots. Parallel row and column addressing of an array of quantum dots QDs can be performed using an interconnect structure as described previously, while limiting the number of control signals required.

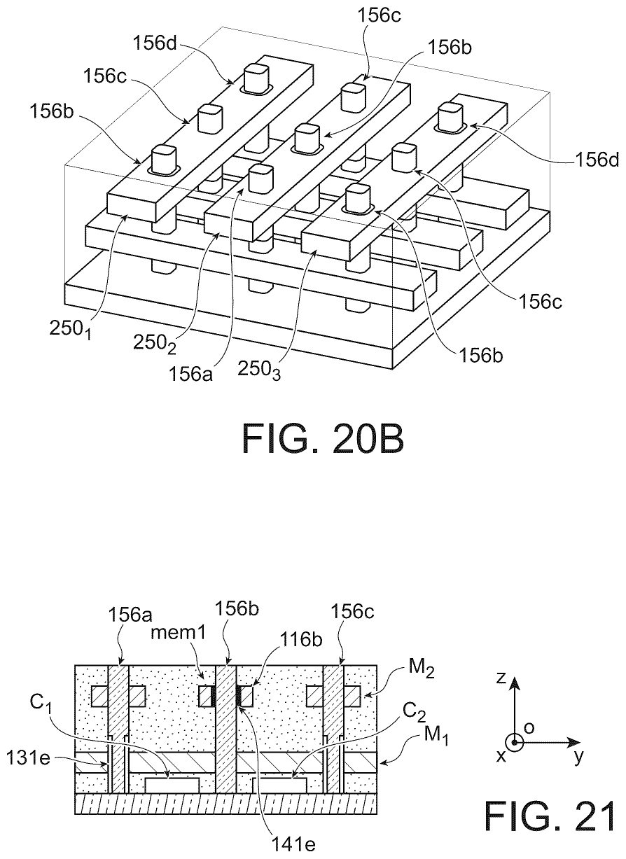

Thus, in a particular example embodiment illustrated in FIG. 20A and 20B, the conductive elements 156a, 156b, 156c have their lower ends respectively contacting regions 102A, 102B, 102C, which are typically semiconductor regions and, for example, of the same semiconductor layer and each forming a quantum dot associated with a Qubit QD21, QD22, QD23.

A conductive element 156a makes it possible to electrically connect a conductive track 116a of an upper level M2 with a region 102A forming a Qubit QD21 while being insulated from a conductive track 106 of the lower level M1 via an insulating spacer 131e. Another conductive element 156b makes it possible to electrically connect a conductive track 106a of the lower level M1 with a region 102B forming another Qubit QD22 while being insulated from a conductive track 116b of the upper level M2 via an insulating spacer 141e.

A particular staggered arrangement of the conductive through-elements or through-vias can be provided for the two-dimensional network of Qubits.

Such an example of a staggered arrangement is illustrated in FIG. 20B, where the conductive elements have a matrix arrangement in different rows 250₁,205₂, 250₃, . . . , 250ₘ, each row being formed by an alternation of conductive elements 156b, 156d connected to the lower metal level M1 and insulated from the upper metal level M2 and conductive elements 156a, 156c connected to the upper metal level M2 and insulated from the lower metal level M1, this alternation being offset from one row to the other. Thus, a first row 250₁ comprises, at its end, a conductive element 156b connected to the lower metal level M1 and insulated from the upper metal level M2. A next, adjacent row 250₂ with typically the same number of Qubits as the first row 250₁, comprises, at its end, a conductive element 156a this time connected to the upper metal level M2 and insulated from the lower metal level M1, whereas a row 250₃ adjacent to the next 250₂ and with typically the same number of Qubits as rows 250₁, 250₂, comprises, at its end, a conductive element 156b insulated from the upper metal level M2 while being connected to the lower metal level M1. A same row 250₂ can thus comprise an alternation of Qubits QD21, QD23 controlled by a track of an upper metal level and a track of qbits QD22 controlled by a track of an upper metal level.

Such an arrangement is conducive to the implementation of an error correction, for example of the “Surface Code” type, as proposed by Fowler et al. in the document “Surface codes: Towards practical large-scale quantum computation”, Phys review A, 2012.

In the example embodiment illustrated in FIG. 21, an interconnect structure of a type as described above can be adapted to addressing and/or biasing one or more circuits or components C₁, C₂, for example transistors, capacitors, resistors or those provided with transistors formed at least partially in the layer 102 on which lie the conductive elements 156a, 156b, 156c. Again, one or more conductive elements 156a, 156c are insulated from a lower level M1 while being coupled to an upper level M2, whereas one or more other conductive elements 156b are coupled to the lower level M1 while being insulated from the upper level M2. A particular embodiment, shown here in FIG. 21 furthermore provides that at least one conductive element 156b, in this case coupled to the lower level M1, forms, with a conductive track 156b of the second level M2 through which it passes, a non-volatile memory element mem1.

In this case, the insulating spacer 141e which is arranged between this conductive track 116b and the conductive through-element 156b, is provided with a specific material, in particular a material whose resistance is likely to be reversibly changed under the effect of an electrical current, or a material whose state is likely to be reversibly changed from an amorphous state to a crystalline state and from a crystalline state to an amorphous state.

The conductive element 156b and the conductive track 116b thus form respectively a first electrode and a second electrode between which the variable phase change and/or variable resistance material is disposed. The non-volatile memory element mem1 can thus be, for example, a ReRAM (“Resistive Random-Access Memory”) memory element, in particular an OxRAM memory element. In this case, the insulating spacer 141e can, for example, be provided based on at least one of the following materials: HfO₂, TiO₂, Al₂O₃, TaOₓ, ZrOₓ.

Alternatively, the non-volatile memory element mem1 can be of the PCRAM (“Phase-Change Random Access Memory”) type. In this case, the insulating spacer 141e can, for example, be provided such that it comprises a chalcogenide material, for example such as GST (GeSbTe).

The implementation of such ReRAM or PCRAM memory elements can make it possible to form, for example, structures of the 1T1R type where a transistor is associated with such a memory element formed at a via.

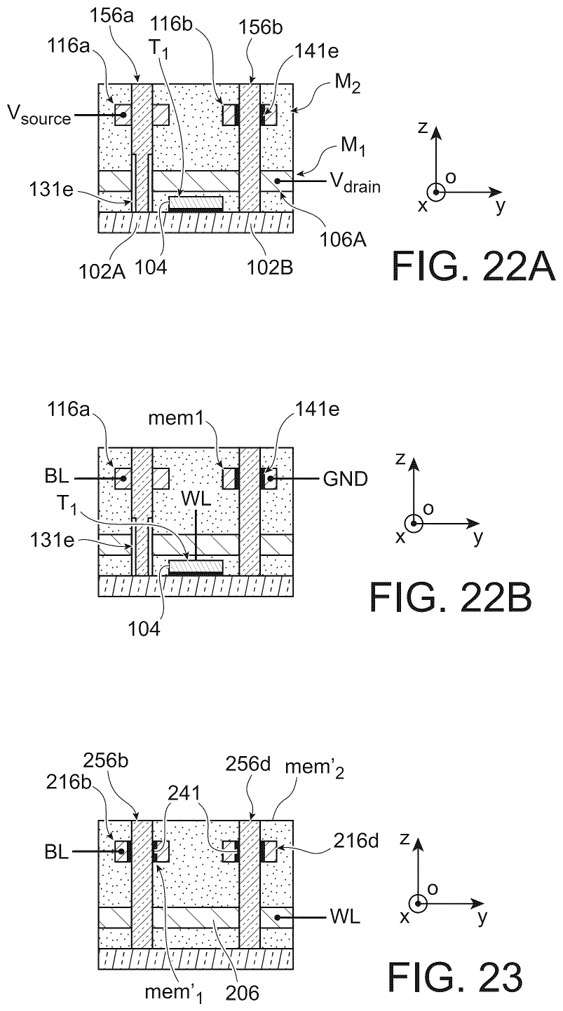

A particular example embodiment of such a structure illustrated in FIG. 22A-22B provides that conductive elements 156a, 156b vertically passing through are arranged on either side of a gate 104 of a transistor T₁ and make contact respectively with a region 102A from among a source region and a drain region of the transistor T₁ and with a second region 102B from among a drain region and a source region that are distinct from the first region.

One particular operating mode is illustrated in FIG. 22A. The conductive element 156a connected to the level M2 while being insulated from the level M1 via its spacer 131e makes it possible to apply a bias potential Vsource to the region 102A of the transistor T₁ which in this particular example forms a source region. In this case, this bias potential is carried by the conductive track 116a with which the conductive element 156a is in contact and through which it passes. The other conductive element 156b connected to the level M1 while being insulated from the upper level M2 via its spacer 141e makes it possible to apply a bias potential Vdrain to the region 102B of the transistor T1 which, in this particular example, forms a drain region. In this case, this bias potential is carried by the conductive track 106a through which the two elements 156a, 156b pass but with which only the other element 156b is electrically connected. Such an interconnect structure is thus used to bias a transistor T₁ (the biasing of the gate 104 being not shown here) while limiting the overall dimensions. The conductive element 156b can form, with a conductive track 116b of level M2, a volatile memory element which, in this operating mode, is not used.

FIG. 22B illustrates another operating mode wherein the conductive track 116a forms a bit line BL for addressing a memory structure, which is connected in this case to the region 102A of the transistor T₁, whereas a word line WL for addressing the memory structure is connected in this case to the gate 104 of the transistor T₁, the region 102B of the transistor being connected in series with a non-volatile memory element mem1 formed by the conductive element 156b, its insulating spacer 141e, and the conductive track 116b through which this conductive element 156b passes and against which the insulating spacer 141e is arranged. A memory cell of the type 1T1R is thus formed by the transistor T1 in series with the memory element mem1, a bit which can be stored via the spacer 141e according to its state, and the transistor T1 herein serving as a selection transistor also referred to as a “selector”.

Another example of a structure given in FIG. 23, provides this time for vertical conductive elements 256b, 256d passing respectively through a first conductive track 216b and a second conductive track 216d at the same level as the first, while being insulated respectively by means of insulating spacers 241e from these tracks 216b, 216d.

Each of the vertical conductive elements 256b, 256d further passes through a same third conductive track 206 of a different level and is electrically connected to this same third conductive track 206.

Again, non-volatile memory elements mem′1, mem′2 can each be formed by a horizontal conductive track 216b (respectively 216d) forming a first electrode, a spacer 241e forming a memory layer, and a vertical conductive element 256b (respectively 216d) forming a first electrode.

The tracks 216b and 216d can be used here for example as bit lines BL, whereas the conductive track 206 of a different level forms for example a word line WL.

An interconnect structure as described previously finds applications in particular in the biasing of 3D circuits with stacked levels of semiconductor layers, in the production of memory circuits, and in the addressing of matrix circuits, in particular of memory matrices or of quantum dot or qubit matrices.

1. A microelectronic device comprising:
a substrate coated with a stack comprising one or more conductive tracks of a lower level, said lower level being coated with an intermediate insulating layer, the intermediate insulating layer being coated with one or more conductive tracks of a so-called “upper” level,
a conductive element passing through the intermediate insulating layer and in contact with a first conductive track of the lower level while being insulated, with an insulating spacer, from a second conductive track, the second conductive track being of the upper level, the insulating spacer being disposed between the second conductive track and the conductive element, said conductive element having a lower end making contact with a first conductor or semiconductor region of the substrate or of the stack,
said conductive element passing through the first conductive track and the second conductive track and being surrounded by said insulating spacer, the device further comprising:
a second conductive element having a lower end making contact with a second conductor or semiconductor region of the substrate or of the stack, the second conductive element passing through a conductive track of the upper level as well as the intermediate insulating layer and a conductive track of the lower level, the second conductive element being insulated, with a second insulating spacer, from said conductive track of the lower level through which the second conductive element passes, the second conductive element being in contact with said conductive track of the upper level through which it passes.

2. An electronic device according to claim 1, wherein the conductive element and the second conductive element each pass through the first conductive track of the lower level and each pass through the second conductive track of the upper level.

3. The electronic device according to claim 1,
wherein the conductive element and the second conductive element each pass through the first conductive track of the lower level and respectively pass through the second conductive track of the upper level and a third conductive track of the upper level that is separate from the second conductive track, the second conductive track and the third conductive track extending parallel or substantially parallel to a first direction parallel to a main plane of the substrate, the first conductive track extending in a second direction orthogonal to the first direction, or
wherein the conductive element and the second conductive element each pass through the second conductive track of the upper level and respectively the first conductive track and a third conductive track of the lower level.

4. The electronic device according to claim 1, wherein the stack comprises a lower insulating layer on which said one or more conductive tracks of the lower level are disposed, the first region being disposed between an area of the substrate and said lower level, the conductive element further passing through the lower insulating layer.

5. The electronic device according to claim 1, wherein the first region is a region of a semiconductor layer of the substrate or resting on the substrate.

6. The electronic device according to claim 1, wherein the first region forms a quantum dot.

7. The electronic device according to claim 1, wherein the first region is a source or drain region of a transistor.

8. The electronic device according to claim 1, wherein said insulating spacer is made of a material capable of reversibly changing resistance and/or state between an amorphous phase and a crystalline phase, in particular under the effect of an electrical current.

9. The electronic device according to claim 2, wherein the first region is a region of a semiconductor layer, and the second region is another region of said semiconductor layer.

10. A method for producing a microelectronic device, which method comprises the following steps:
a) providing a substrate coated with a stack comprising one or more conductive tracks of a lower level, the lower level being coated with an intermediate insulating layer, the intermediate insulating layer being coated with one or more conductive tracks of a so-called upper level,
b) forming a first opening and a second opening in the stack, each passing through a conductive track of the upper level, the intermediate insulating layer, and a conductive track of the lower level, the first opening exposing at least one first portion and the second opening exposing at least one second portion respectively of one or more conductive tracks of said upper level, the first opening further exposing at least one third portion and the second opening further exposing at least one fourth portion respectively of one or more conductive tracks of said lower level,
c) forming, in the first opening, a first insulating spacer against the first portion of conductive track while leaving the third portion of conductive track exposed, and forming, in the second opening, a second insulating spacer against the fourth portion of conductive track while leaving the second portion of conductive track exposed,
d) filling the first opening and the second opening with at least one conductive material, so as to form a first conductive element and a second conductive element, the first conductive element being in contact with the third portion while being insulated from the first portion via the first spacer, and the second conductive element being in contact with the second portion while being insulated from the fourth portion via the second spacer.

11. The method according to claim 10, wherein step c) comprises at least the following steps:
c1) depositing a first thin insulating layer lining the walls of the first opening and of the second opening,
c2) partially etching the first thin insulating layer at said upper part of the first opening, so as to expose the first portion, while preserving the first thin insulating layer at said lower part of the first opening as well as in the second opening,
c3) partially etching the first portion, so as to form a cavity,
c4) depositing a second thin insulating layer lining the walls of the second opening and of the first opening, and filling the cavity at least partially,
c5) etching the second thin insulating layer, so as to preserve a region of the second thin insulating layer in the cavity.

12. The method according to claim 11, wherein after step c1) and before step c2), the method comprises the following steps:
depositing at least one sealing material for sealing off the first opening and the second opening,
forming a masking opposite the second opening and comprising a window opposite the first opening,
etching, through said window, said at least one sealing material in an upper part of the first opening while preserving the sealing material in a lower part of the first opening, the method further comprising, after step c2) and before step c3):
removing the sealing material from the first opening and second opening.

13. The method according to claim 1, wherein the first thin insulating layer and the second thin insulating layer are respectively made from at least one first material and at least one second material that is different from the first material, the step c5) of etching, one or more times, the second thin insulating layer being carried out by selectively etching the second material with respect to the first material, followed by anisotropically etching the first thin insulating layer.

14. The method according to claim 1, wherein the substrate or the stack comprises a semiconductor layer coated with at least one so-called “lower” insulating layer, the lower insulating layer being coated by the one or more conductive tracks of the lower level and wherein in step b) of forming a first opening and a second opening, the first opening and the second opening are formed so as to pass through the lower insulating layer until reaching said semiconductor layer.

15. The method according to claim 1, wherein the first opening and the second opening are formed simultaneously in step b) and wherein the filling of the first opening and of the second opening in step d) is advantageously carried out simultaneously in the first opening and in the second opening.
